(19) United States
(12) Patent Application Publication
(10) Pub. No.: US 2023/0137822 A1
(43) Pub. Date: May 4, 2023

(54) DISPLAY PANEL AND METHOD OF MANUFACTURING THE SAME

(71) Applicant: Samsung Display Co., LTD., Yongin-si (KR)

(72) Inventors: INKYUNG YOO, Hwaseong-si (KR); HEENA KIM, Hwaseong-si (KR); SANG JIN LEE, Suwon-si (KR)

(21) Appl. No.: 17/879,472

(22) Filed: Aug. 2, 2022

(30) Foreign Application Priority Data
Oct. 29, 2021 (KR) 10-2021-0146985

(51) Int. Cl. H01L 27/32; H01L 51/52; H01L 51/56

(52) U.S. Cl. CPC H01L 27/3262; H01L 27/3246; H01L 27/3234; H01L 51/5253; H01L 51/56; H01L 2227/323

(57) ABSTRACT

A display panel that includes a substrate that has a first area, a second area surrounding the first area, a third area surrounding the second area, a partition on the substrate in the second area, a first layer and a second layer on the first layer, and at least one groove on an upper surface of the second layer and a display element layer on the substrate in the third area and adjacent to the partition is provided.

### CROSS-REFERENCE TO RELATED APPLICATION

This application claims priority to and the benefit of Korean Patent Application No. 10-2021-0146985 filed on Oct. 29, 2021 in the Korean Intellectual Property Office (KIPO), the entire content of which is hereby incorporated by reference.

### BACKGROUND

### 1. Field

Embodiments of the present disclosure relate to a display panel. For example, embodiments relate to the display panel and a method of manufacturing the same.

### 2. Description of the related art

A display device is a device including a display panel that displays an image for providing visual information to a user.

A functional module (e.g., a camera module, etc.) may be provided in the display device so that a user may perform various suitable functions using the display device. In order for the functional module to function efficiently, it is beneficial to increase a transmittance of external light incident on the functional module. In addition, recently, in order to enlarge a display area of the display device, a structure in which the functional module is provided to overlap the display area has been developed.

### SUMMARY

Embodiments of the present disclosure are directed to a display panel in which a manufacturing process is simplified.

Other embodiments are directed to a method of manufacturing the display panel.

A display panel according to an embodiment may include a substrate including a first area, a second area surrounding the first area, and a third area surrounding the second area, a partition on the substrate in the second area, including a first layer and a second layer on the first layer, and defining (including) at least one groove on an upper surface of the second layer and a display element layer on the substrate in the third area and adjacent to the partition.

In an embodiment, a depth of the groove may be less than a length from an upper surface of the substrate to the upper surface of the second layer.

In an embodiment, a hole overlapping the first area may be defined in (included in) the partition and the substrate.

In an embodiment, the groove may have a ring shape surrounding the hole in a plan view.

In an embodiment, the first layer and the second layer may include the same material.

In an embodiment, the display element layer may include a transistor, a first electrode on the transistor and connected to the transistor, a light emitting layer on the first electrode and a second electrode on the light emitting layer.

In an embodiment, the display panel may further include a planarization layer in the third area and between the transistor and the first electrode.

In an embodiment, the planarization layer may include the same material as the first layer.

In an embodiment, the display panel may further include a pixel defining layer on the planarization layer, under the second electrode, and in the third area.

In an embodiment, the pixel defining layer may include the same material as the second layer.

A method of manufacturing a display panel according to an embodiment may include forming a first layer on a substrate and in a first area and a second area surrounding the first area, forming a second layer on the first layer in the first area and the second area, forming at least one groove on an upper surface of the second layer and forming a display element layer on the substrate and in a third area surrounding the second area.

In an embodiment, the method may further include forming a hole penetrating the first layer, the second layer, and the substrate and forming a filling layer overlapping the first area in the hole.

In an embodiment, the groove may have a ring shape surrounding the hole in a plan view.

In an embodiment, forming the hole may include forming a first opening overlapping the first area in the second layer, forming a second opening overlapping the first area in the first layer, and forming a third opening overlapping the first area in the substrate.

In an embodiment, the groove may overlap at least one of the first area and the second area.

In an embodiment, forming the display element layer may include forming a transistor, forming a first electrode connected to the transistor on the transistor, forming a light emitting layer on the first electrode, and forming a second electrode on the light emitting layer.

In an embodiment, forming the display element layer may further include forming a planarization layer on the transistor.

In an embodiment, the planarization layer may be formed concurrently (e.g., simultaneously) with the first layer.

In an embodiment, forming the display element layer may further include forming a pixel defining layer on the first electrode.

In an embodiment, the pixel defining layer may be formed concurrently (e.g., simultaneously) with the second layer.

In a display device according to embodiments of the present disclosure, at least one groove may be formed on the upper surface of an organic layer located between the hole area and the display area. By forming the groove on the upper surface of the organic layer, an additional process for flattening the step may be omitted. Accordingly, a manufacturing process of the display panel may be simplified, and a manufacturing time and cost for manufacturing the display panel may be reduced.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a plan view of a display device according to an embodiment.

FIG. 2 is a cross-sectional view taken along line I-I′ of FIG. 1.

FIG. 3 is a cross-sectional view illustrating a display panel included in the display device of FIG. 1.

FIG. 4 is an enlarged plan view of area A of FIG. 1.

FIG. 5 is a cross-sectional view taken along line II-II′ of FIG. 4.

FIG. 6 is a cross-sectional view illustrating a method of manufacturing a display panel according to an embodiment.

FIG. 7 is a cross-sectional view illustrating a portion of a method of manufacturing a display panel according to an embodiment.

FIG. 8 is a cross-sectional view illustrating a portion of a method of manufacturing a display panel according to an embodiment.

FIG. 9 is a cross-sectional view illustrating a portion of a method of manufacturing a display panel according to an embodiment.

FIG. 10 is a cross-sectional view illustrating a portion of a method of manufacturing a display panel according to an embodiment.

FIG. 11 is a cross-sectional view illustrating a portion of a method of manufacturing a display panel according to an embodiment.

FIG. 12 is a cross-sectional view illustrating a portion of a method of manufacturing a display panel according to an embodiment.

FIG. 13 is a cross-sectional view illustrating a portion of a method of manufacturing a display panel according to an embodiment.

FIG. 14 is a cross-sectional view illustrating a portion of a method of manufacturing a display panel according to an embodiment.

### DETAILED DESCRIPTION

Hereinafter, display devices in accordance with embodiments will be described in more detail with reference to the accompanying drawings. The same reference numerals are used for the same components in the drawings, and duplicative descriptions thereof may not be repeated.

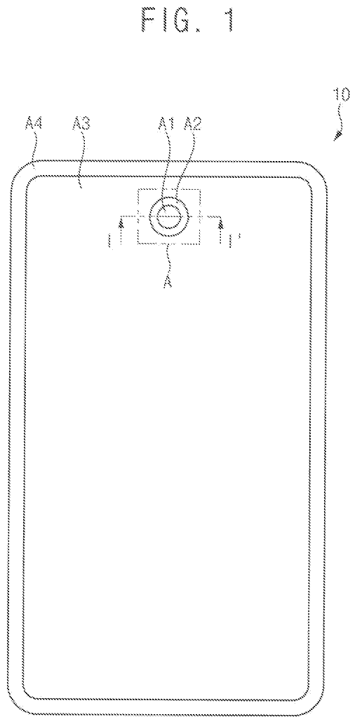

FIG. 1 is a plan view of a display device according to an embodiment.

Referring to FIG. 1, a display device 10 may be divided into a first area A1, a second area A2, a third area A3, and a fourth area A4.

The first area A1 may be a non-display area that does not display a screen (e.g., does not display an image). The first area A1 may be an area that transmits external light. For example, the first area A1 may be a hole area in which a hole (opening) is located, and a functional module may be in the first area A1.

The second area A2 may surround the first area A1. The second area A2 may be a boundary between the first area A1 and the third area A3. The third area A3 may surround the second area A2. The third area A3 may be a display area for displaying a screen. A display element layer including pixels may be in the third area A3. The fourth area A4 may surround the third area A3. The fourth area A4 may be a non-display area that does not display a screen. A driver that transmits signals and voltages to the third region A3 and a control unit that controls the driving unit may be in the fourth area A4.

However, the embodiments are not limited thereto, and for example, pixels may be in the first area A1, the second area A2, and the fourth area A4, and the first area A1, the second area A2, and the fourth area A4 may also display a screen.

The first area A1 may be at an edge of the third area A3. Each of the first area A1 and the second area A2 may have a substantially circular shape. Each of the third area A3 and the fourth area A4 may have a rectangular shape with rounded corners. However, a shape of each of the first area A1, the second area A2, the third area A3, and the fourth area A4 are not limited thereto, and each of the first area A1, the second area A2, the third area A3, and the fourth area A4 may have one of various suitable shapes such as a rectangle or a circle.

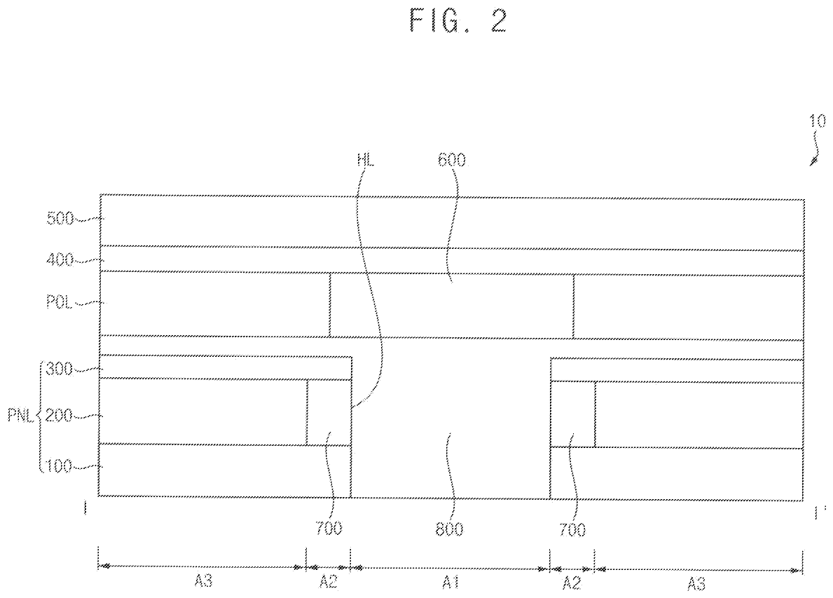

FIG. 2 is a cross-sectional view taken along line I-I′ of FIG. 1.

Referring to FIGS. 1 and 2, the display device 10 may include a display panel PNL, a functional module, a polarization layer POL, a resin layer 600, an adhesive layer 400, and a window 500. The display panel PNL may include a substrate 100, a display element layer 200, a barrier part 700, a filling layer 800, and an encapsulation layer 300.

The substrate 100 may include a transparent or opaque material. The substrate 100 may include glass, quartz, plastic, and/or the like.

The functional module may be under the substrate 100. The functional module may overlap the first area A1. Examples of the functional module may include a camera module, a face recognition sensor module, a pupil recognition sensor module, an acceleration sensor module, a proximity sensor module, an infrared sensor module, a geomagnetic sensor module, and an illuminance sensor module. The camera module may be a module that captures (or recognizes) an image of an object located in front of the display device. The face recognition sensor module may be a module for detecting a user's face. The pupil recognition sensor module may be a module for detecting a user's pupil. The acceleration sensor module and the geomagnetic sensor module may be modules for determining a movement of the display device. The proximity sensor module and the infrared sensor module may be modules for detecting whether a front surface of the display device is in proximity. The illuminance sensor module may be a module for measuring a degree of external brightness.

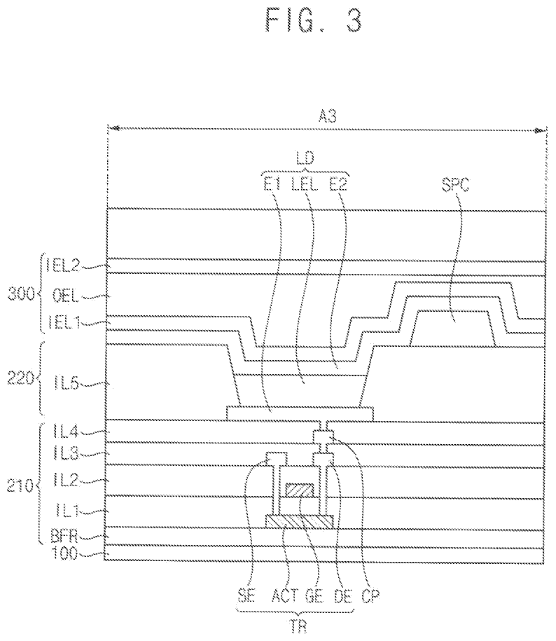

The display element layer 200 may be on the substrate 100 in the third area A3. The display element layer 200 may include a circuit element layer (e.g., the circuit element layer 210 of FIG. 3) and a light emitting element layer (e.g., the light emitting element layer 220 of FIG. 3). The circuit element layer 210 may include insulation layers and conductive layers. The light emitting element layer 220 may be on the circuit element layer 210. The light emitting element layer 220 may include a fifth insulation layer (e.g., the fifth insulation layer IL5 of FIG. 3) and a light emitting diode (e.g., the light emitting diode LD of FIG. 3). The light emitting element layer 220 may emit light, and the circuit element layer 210 may drive the light emitting element layer 220.

The barrier part 700 may be on the substrate 100 in the second area A2. Wirings may be under the barrier part 700. The barrier part 700 may cover the wirings and may have a substantially flat upper surface without creating a step around the wirings. The barrier part 700 may prevent or reduce the wirings from being visually recognized from the outside.

The encapsulation layer 300 may be on the display element layer 200 and the barrier part 700. The encapsulation layer 300 may prevent or reduce moisture and oxygen from penetrating into the display element layer 200 from the outside.

The filling layer 800 may be on the substrate 100 in the first area A1, the second area A2, and the third area A3. The filling layer 800 may fill an opening overlapping the first area A1. Because the first area A1 is a light-transmitting area, light may pass through the display panel PNL through the opening. Accordingly, the light may be incident on the functional module under the display panel PNL through the opening.

The polarization layer POL may be on the filling layer 800. The polarization layer POL may overlap the third area A3. The polarization layer POL may partially or entirely overlap the second area A2. The polarization layer POL may selectively transmit light emitted from the display element layer 200.

The resin layer 600 may be on the filling layer 800. The resin layer 600 may fill an opening overlapping the first area A1 on the filling layer 800. Because the first area A1 is a light-transmitting area, light may pass through the display panel PNL through the opening. Accordingly, the light may be incident on the functional module under the display panel PNL through the opening.

The adhesive layer 400 may be on the polarizing layer POL and the resin layer 600. The adhesive layer 400 may include an adhesive material, and may adhere the window 500 to a lower structure including the polarizing layer POL.

The window 500 may be on the adhesive layer 400. The window 500 may protect the lower structure and allow external light to enter the functional module. Accordingly, the window 500 may be formed of transparent glass or transparent plastic.

FIG. 3 is a cross-sectional view illustrating a display panel included in the display device of FIG. 1.

Referring FIGS. 2 and 3, the display panel PNL may include a substrate 100, a display element layer 200, a barrier part 700, a filling layer 800, and an encapsulation layer 300. The display element layer 200 may include a circuit element layer 210 and a light emitting element layer 220.

The circuit element layer 210 may be on the substrate 100, and may include a buffer layer BFR, at least one transistor TR, a connection electrode CP, a first insulation layer IL1, and a second insulation layer IL2, a third insulation layer IL3, and a fourth insulation layer IL4. The transistor TR may include an active layer ACT, a gate electrode

GAT, a source electrode SE, and a drain electrode DE. The light emitting element layer 220 may be on the circuit element layer 210 and may include a fifth insulation layer IL5, a spacer SPC, and a light emitting diode LD. The light emitting diode LD may include a first electrode E1, a light emitting layer LEL, and a second electrode E2.

The buffer layer BFR may be on the substrate 100. The buffer layer BFR may prevent or reduce diffusion of metal atoms or impurities from the substrate 100 into the active layer ACT.

The active layer ACT may be on the substrate 100. The active layer ACT may be divided into a source region and a drain region doped with impurities, and a channel region between the source region and the drain region.

The first insulation layer IL1 may be on the buffer layer BFR. The first insulation layer IL1 may cover the active layer ACT and may have substantially the same thickness along a profile (e.g., outer surface) of the active layer ACT. However, the present disclosure is not limited thereto. In an embodiment, the first insulation layer IL1 may include an inorganic material.

The gate electrode GAT may be on the first insulation layer IL1. In an embodiment, the gate electrode GAT may overlap the channel region of the active layer ACT.

The second insulation layer IL2 may be on the first insulation layer IL1. In an embodiment, the second insulation layer IL2 may cover the gate electrode GAT and may have substantially the same thickness along a profile (e.g., outer surface) of the gate electrode GAT. However, the present disclosure is not limited thereto.

The source electrode SE and the drain electrode DE may be on the second insulation layer IL2. The source electrode SE may contact the source region of the active layer ACT through a first contact hole formed in the first and second insulation layers IL1 and IL2. The drain electrode DE may contact the drain region of the active layer ACT through a second contact hole formed in the first and second insulation layers IL1 and IL2.

The third insulation layer IL3 may be on the second insulation layer IL2. In an embodiment, the third insulation layer IL3 may cover the source and drain electrodes SE and DE, and may have a substantially flat upper surface without creating a step around the source and drain electrodes SE and DE. In an embodiment, the third insulation layer IL3 may include an organic material.

The connection electrode CP may be on the third insulation layer IL3. The connection electrode CP may contact the source electrode SE or the drain electrode DE through a second contact hole formed in the third insulation layer IL3.

The fourth insulation layer IL4 may be on the third insulation layer IL3. In an embodiment, the fourth insulation layer IL4 may cover the connection electrode CP, and may have a substantially flat upper surface without creating a step around the connection electrode CP. In an embodiment, the fourth insulation layer IL4 may include an organic material.

Each of the third insulation layer IL3 and the fourth insulation layer IL4 may be referred to as a planarization layer.

The first electrode E1 may be on the fourth insulation layer IL4. The first electrode E1 may have reflective or transmissive properties. In an embodiment, the first electrode E1 may include a metal.

The first electrode E1 may contact the connection electrode CP through a third contact hole formed in the fourth insulation layer IL4. Through this, the first electrode E1 may be connected to the transistor TR.

The fifth insulation layer IL5 may be on the fourth insulation layer IL4, and an opening exposing an upper surface of the first electrode E1 may be defined in (included in) the fifth insulation layer IL5. In an embodiment, the fifth insulation layer IL5 may include an organic material or an inorganic material.

The fifth insulation layer IL5 may be referred to as a pixel defining layer.

The spacer SPC may be on the fifth insulation layer IL5. In an embodiment, the spacer SPC may include an organic material or an inorganic material. The spacer SPC may maintain a gap between the encapsulation layer 300 and the substrate 100.

The spacer SPC may include a material different from that of the fifth insulation layer IL5. The spacer SPC may be formed after the fifth insulation layer IL5 is formed. However, embodiments according to the present disclosure are not limited thereto, and the spacer SPC may include the same material as the fifth insulation layer IL5. For example, the fifth insulation layer IL5 and the spacer SPC may include an organic material such as polyimide. In an embodiment, the fifth insulation layer IL5 and the spacer SPC may be concurrently (e.g., simultaneously) formed using a halftone mask.

The light emitting layer LEL may be on the first electrode E1. The light emitting layer LEL may be in the opening formed in the fifth insulation layer IL5. In an embodiment, the light emitting layer LEL may have a multilayer structure including a hole injection layer, a hole transport layer, an organic emission layer, an electron transport layer, and an electron injection layer. The organic emission layer may include a light emitting material.

The second electrode E2 may cover the light emitting layer LEL, and may be on the fifth insulation layer IL5 and the spacer SPC. In an embodiment, the second electrode E2 may have a plate shape. In an embodiment, the second electrode E2 may have transmissive or reflective properties. In an embodiment, the second electrode E2 may include a metal.

The encapsulation layer 300 may prevent or reduce moisture and oxygen from penetrating into the light emitting diode LD from the outside. In an embodiment, the encapsulation layer 300 may include a first inorganic encapsulation layer IEL1, an organic encapsulation layer OEL, and a second inorganic encapsulation layer IEL2.

The first inorganic encapsulation layer IEL1 may be on the second electrode E2 to have substantially the same thickness along a profile (e.g., outer surface) of the second electrode E2. The organic encapsulation layer OEL may be on the first inorganic encapsulation layer IEL1, and may have a substantially flat upper surface without creating a step around the first inorganic encapsulation layer IEL1. The second inorganic encapsulation layer IEL2 may be on the organic encapsulation layer OEL.

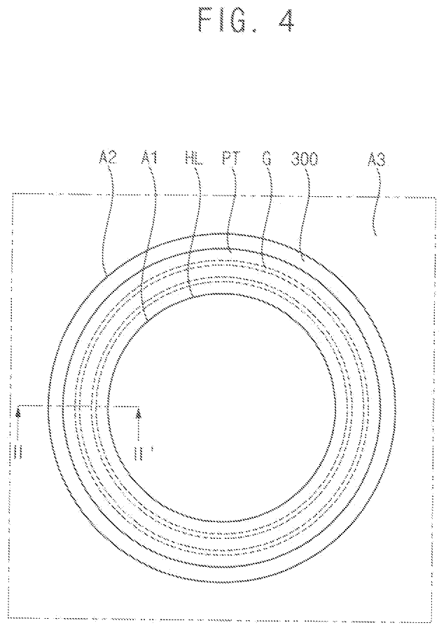

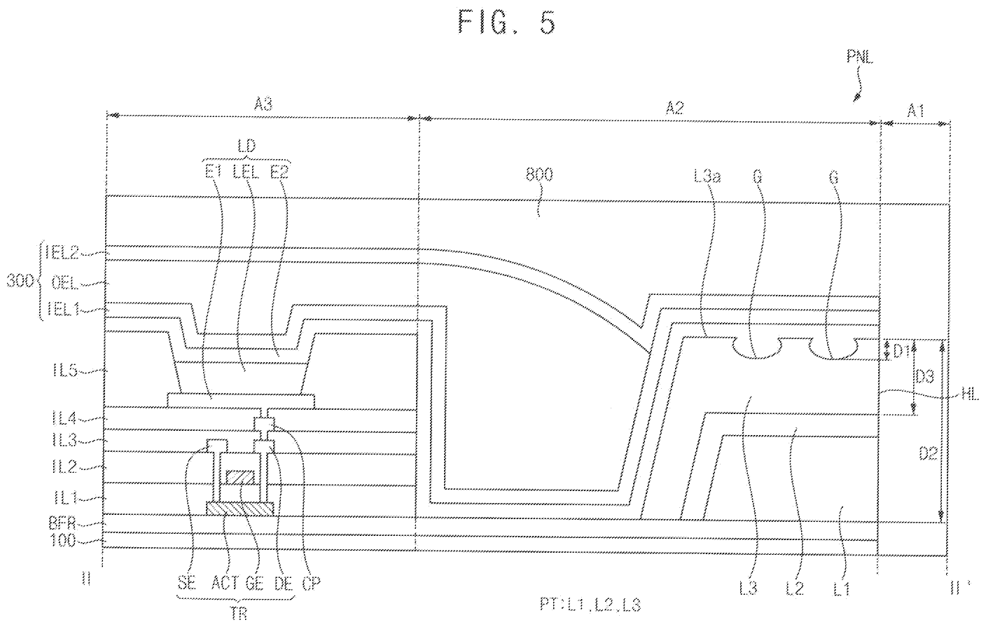

FIG. 4 is an enlarged plan view of area A of FIG. 1. FIG. 5 is a cross-sectional view taken along line II-II′ of FIG. 4. FIGS. 4 and 5 may be figures for explaining a display panel PNL included in the display device 10 of FIG. 1.

Referring to FIGS. 2 to 5, the barrier part 700 may include the partition PT. The partition PT may be on the substrate 100. The partition PT may be in the second area A2. The partition PT may be adjacent to the display element layer 200. However, in another embodiment, the partition PT may be spaced apart from the display element layer 200.

The partition PT may include a first layer L1, a second layer L2, and a third layer L3. The second layer L2 may be on the first layer L1, and the third layer L3 may be on the second layer L2.

The first inorganic encapsulation layer IEL1 may be on the third layer L3. The second inorganic encapsulation layer IEL2 may be on the first inorganic encapsulation layer IEL1 on the partition PT. For example, the first inorganic encapsulation layer IEL1 and the second inorganic encapsulation layer IEL2 may extend from the third area A3 to the second area A2. The organic encapsulation layer OEL may be adjacent to the partition PT.

The first layer L1, the second layer L2, and the third layer L3 may include the same material. Each of the first layer L1, the second layer L2, and the third layer L3 may include an organic insulating material. Examples of the organic insulating material constituting each of the first layer L1, the second layer L2, and the third layer L3 may include polyacrylate resin, epoxy resin, and phenolic resin, polyamides resin, polyimides resin, unsaturated polyesters resin, polyphenylenether resin, polyphenylenesulfide resin or benzocyclobutene (BCB). These substances may be used alone or in combination.

The first layer L1 may include the same material as the third insulation layer IL3 which is the planarization layer. A length from the substrate 100 to an upper surface of the first layer L1 may be substantially the same as a length from the substrate 100 to an upper surface of the third insulation layer IL3.

However, embodiments according to the present disclosure are not limited thereto, and a length from the substrate 100 to the upper surface of the first layer L1 may be different from the length from the substrate 100 to the upper surface of the third insulation layer IL3.

The second layer L2 may include the same material as the fourth insulation layer IL4 which is the planarization layer. A length from the substrate 100 to an upper surface of the second layer L2 may be substantially the same as a length from the substrate 100 to an upper surface of the fourth insulation layer IL4.

The third layer L3 may include the same material as the fifth insulation layer IL5 which is the pixel defining layer. A length from the substrate 100 to an upper surface of the third layer L3 may be substantially the same as a length from the substrate 100 to an upper surface of the fifth insulation layer IL5.

However, embodiments according to the present disclosure are not limited thereto, and the third layer L3 may include the same material as the spacer SPC. The length from the substrate 100 to the upper surface of the third layer L3 may be substantially the same as a length from the substrate 100 to an upper surface of the spacer SPC.

Embodiments according to the present disclosure are not limited thereto, and the length of the first layer L1 from the substrate 100 may be different from the length of the third insulation layer IL3 from the substrate 100. The length of the second layer L2 from the substrate 100 may be different from the length of the fourth insulation layer IL4 from the substrate 100. The length of the third layer L3 from the substrate 100 may be different from the length of the fifth insulation layer IL5 from the substrate 100.

A hole HL overlapping the first area A1 may be defined in (included in) the partition PT and the substrate 100. The hole HL may penetrate the first layer L1, the second layer L2, the third layer L3, the first inorganic encapsulation layer IEL1, the second inorganic encapsulation layer IEL2, and the substrate 100.

The functional module may be under the display panel PNL in which the hole HL is defined. The functional module may be exposed due to the hole HL. External light may be incident on the functional module through the hole HL. The filling layer 800 may be inside the hole HL.

At least one groove G may be defined (included) on the upper surface L3a of the third layer L3. The groove G may be adjacent to the hole HL. When in a plan view, the groove G may have a ring shape surrounding the hole HL.

A depth D1 of the groove G may be less than a length D2 from an upper surface of the buffer layer BFR to the upper surface L3a of the third layer L3. For example, the groove G may not expose the substrate 100. For example, the depth D1 of the groove G may be less than the length D3 from the upper surface of the second layer L2 to the upper surface L3a of the third layer L3. The groove G may be spaced apart from the second layer L2. However, embodiments according to the present disclosure are not limited thereto, and the depth D1 of the groove G may be greater than or equal to the length from the upper surface of the second layer L2 to the upper surface L3a of the third layer L3. In this embodiment, the groove G may penetrate the third layer L3, and the groove G may be defined (included) on the upper surface of the second layer L2.

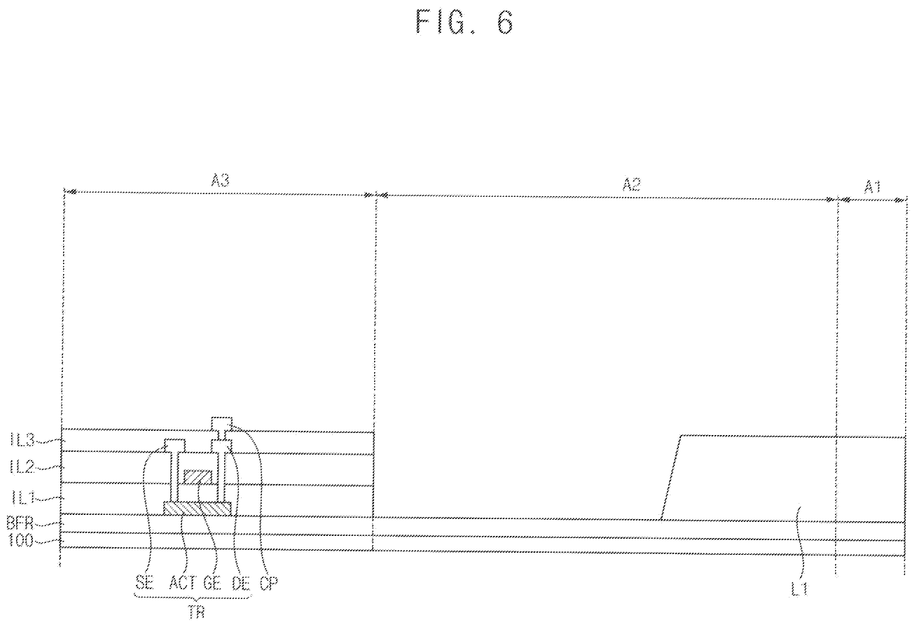

FIGS. 6 to 14 are cross-sectional views illustrating a method of manufacturing a display panel according to an embodiment. For example, the method of manufacturing the display panel may be a method of manufacturing the display panel PNL of FIG. 5.

Accordingly, in the method of manufacturing the display panel PNL described with reference to FIGS. 6 to 14, components which are the same as the display panel PNL described with reference to FIGS. 1 to 5 may be omitted so as to avoid redundancy in the description below.

Referring to FIG. 6, a substrate 100 may be divided into a first area A1, a second area A2, and a third area A3. A buffer layer BFR may be formed on the substrate 100. The substrate 100 and the buffer layer BFR may be formed to overlap the first area A1, the second area A2, and the third area A3.

In the third area A3, an active layer ACT may be formed on the buffer layer

BFR. The first insulation layer IL1 may be formed on the buffer layer BFR to cover the active layer ACT. A gate electrode GE may be formed on the first insulation layer IL1. The second insulation layer IL2 may be formed on the first insulation layer IL1 to cover the gate electrode GE.

A source electrode SE and a drain electrode DE may be formed on the second insulation layer IL2. A first contact hole may be formed in the first insulation layer IL1 and the second insulation layer IL2. Each of the source electrode SE and the drain electrode DE may contact the active layer ACT through the first contact hole. The active layer ACT, the gate electrode GE, the source electrode SE, and the drain electrode DE may form a transistor TR.

A third insulation layer IL3 may be formed on the second insulation layer IL2 to cover the source electrode SE and the drain electrode DE. The third insulation layer IL3 may have a substantially flat upper surface. A connection electrode CP may be formed on the third insulation layer IL3. A second contact hole may be formed in the third insulation layer IL3. The connection electrode CP may contact the source electrode SE or the drain electrode DE through the second contact hole. Accordingly, the connection electrode CP may be connected to the transistor TR.

In the first area A1 and the second area A2, a first layer L1 may be formed on the buffer layer BFR. The first layer L1 may be formed concurrently (e.g., simultaneously) with the third insulation layer IL3. The first layer L1 may include substantially the same material as the third insulation layer IL3. For example, the first layer L1 and the third insulation layer IL3 may include an organic material.

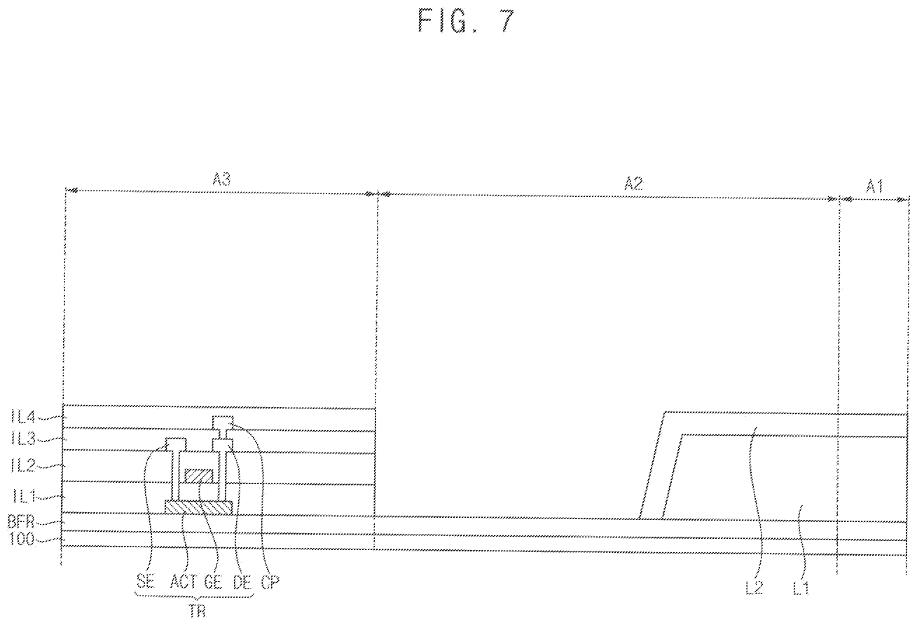

Referring to FIG. 7, in the third area A3, a fourth insulation layer IL4 may be formed on the third insulation layer IL3 to cover the connection electrode CP. The fourth insulation layer IL4 may have a substantially flat upper surface.

In the first area A1 and the second area A2, a second layer L2 may be formed on the first layer L1. The second layer L2 may be formed concurrently (e.g., simultaneously) with the fourth insulation layer IL4. The second layer L2 may include the same material as the fourth insulation layer IL4. For example, the second layer L2 and the fourth insulation layer IL4 may include an organic material.

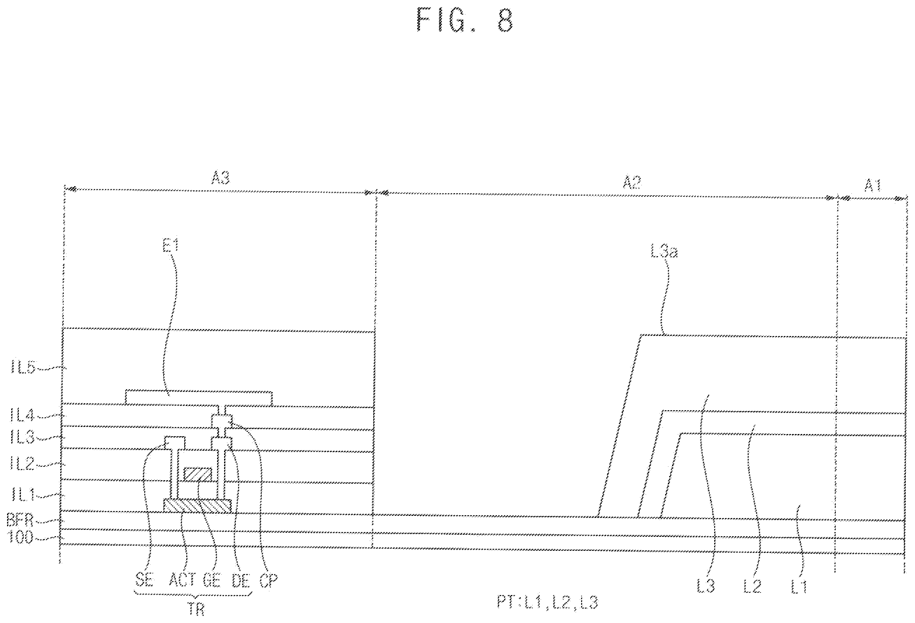

Referring to FIG. 8, in the third area A3, a first electrode E1 may be formed on the fourth insulation layer IL4. A third contact hole may be formed in the fourth insulation layer IL4. The first electrode E1 may contact the connection electrode CP through the third contact hole. Accordingly, the first electrode E1 may be connected to the connection electrode CP. Accordingly, the first electrode E1 may be connected to the transistor TR. A fifth insulation layer IL5 may be formed on the fourth insulation layer IL4 to cover the first electrode E1.

In the first area A1 and the second area A2, a third layer L3 may be formed on the second layer L2. The third layer L3 may be formed concurrently (e.g., simultaneously) with the fifth insulation layer IL5. The third layer L3 may include the same material as the fifth insulation layer IL5. The first to third layers L1, L2, and L3 may form a partition PT.

A spacer (e.g., the spacer SPC of FIG. 3) may be formed on the fifth insulation layer IL5.

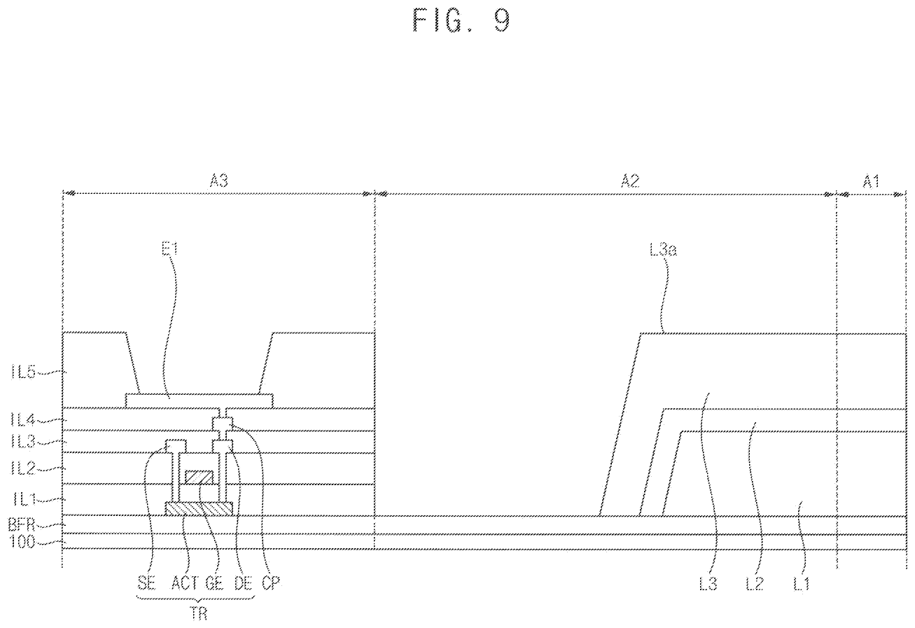

Referring to FIG. 9, an opening penetrating the fifth insulation layer IL5 may be formed in the third area A3. The opening may expose an upper surface of the first electrode E1.

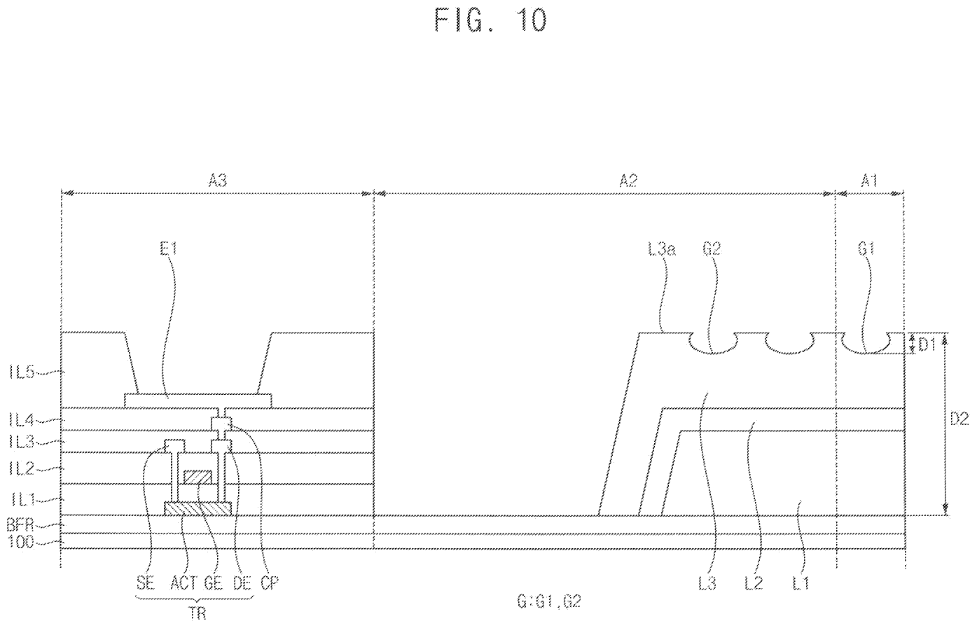

Referring to FIG. 10, in the first area A1 and the second area A2, at least one groove G may be formed on an upper surface L3a of the third layer L3.

The groove G may be formed in which a depth D1 of the groove G is less than a length D2 from an upper surface of the buffer layer BFR to the upper surface L3a of the third layer L3. For example, the groove G may not expose the substrate 100. In an embodiment, the groove G may be formed so as not to expose the buffer layer BFR. However, embodiments according to the present disclosure are not limited thereto, and the groove G may be formed so as not to expose the second layer L2. In an embodiment, the groove G may be formed to expose the second layer L2 and not expose the first layer L1.

The groove G may overlap at least one of the first area A1 and the second area A2. The groove G may include a first groove G1 and a second groove G2. A first groove G1 may be formed in the first area A1. A second groove G2 may be formed in the second area A2.

The second groove G2 overlapping the second area A2 may surround the first area A1. The second groove G2 may be formed in a ring shape. The second groove G2 may be formed outside of a boundary between the first area A1 and the second area A2. Similarly, the first groove G1 overlapping the first area A1 may be formed in the ring shape. The first groove G1 may be formed inside of the boundary between the first area A1 and the second area A2.

The groove G may be formed by a dry etching method. However, embodiments according to the present disclosure are not limited thereto.

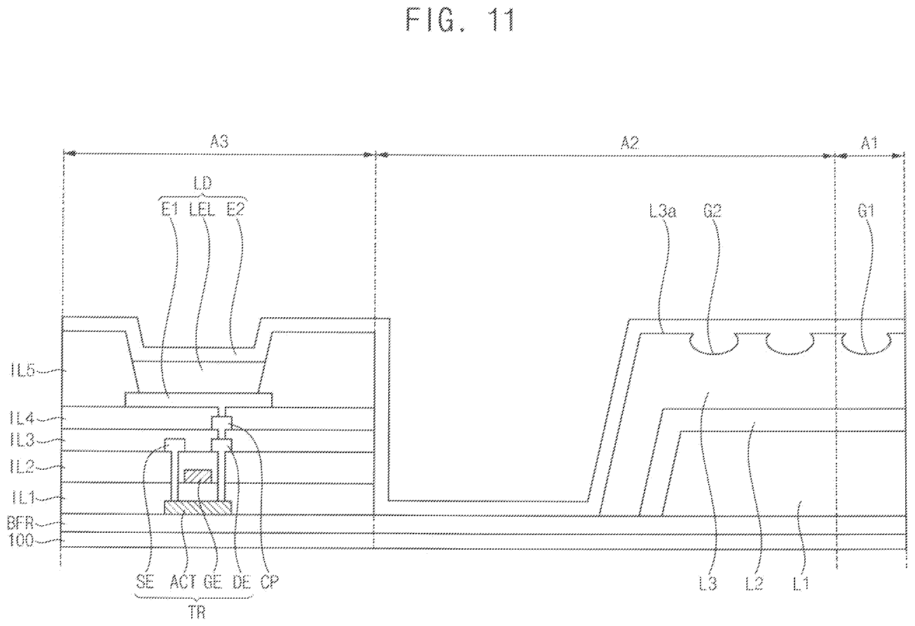

Referring to FIG. 11, in the third area A3, a light emitting layer LEL may be formed on the first electrode E1. The light emitting layer LEL may have a structure in which a hole injection layer, a hole transport layer, an organic emission layer, an electron transport layer, and an electron injection layer are sequentially formed.

The light emitting layer LEL may be formed in the opening. However, embodiments according to the present disclosure are not limited thereto, and the light emitting layer LEL may extend along an upper surface of the fifth insulation layer IL5.

The second electrode E2 may be formed on the fifth insulation layer IL5 to cover the light emitting layer LEL. The second electrode E2 may have a plate shape. The second electrode E2 may extend from the third area A3 to the second area A2. In the third area A3, the second electrode E2 may be formed on the fifth insulation layer IL5 and the light emitting layer LEL. In the second area A2 and the first area A1, the second electrode E2 may be formed on the third layer L3 to cover the groove G.

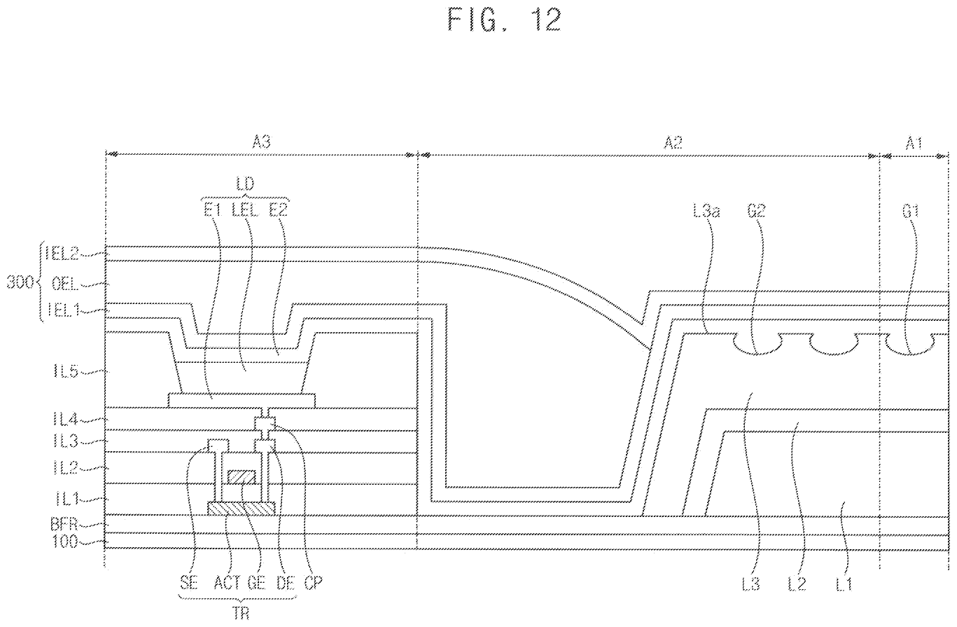

Referring to FIG. 12, in the first area A1, the second area A2, and the third area A3, the encapsulation layer 300 may be formed on the second electrode E2. The encapsulation layer 300 may include a first inorganic encapsulation layer IEL1, an organic encapsulation layer OEL, and a second inorganic encapsulation layer IEL2.

In the first area A1, the second area A2, and the third area A3, the first inorganic encapsulation layer IEL1 may be formed on the second electrode E2. The first inorganic encapsulation layer IEL1 may extend from the third area A3 to the first area A1.

In a portion of the third area A3 and the second area A2, the organic encapsulation layer OEL may be formed on the first inorganic encapsulation layer IEL1. The organic encapsulation layer OEL may extend from the third area A3 to a portion of the second area A2. In the second area A2, the organic encapsulation layer OEL may be formed adjacent to the first layer L1, the second layer L2, and the third layer L3.

In the third area A3, the second inorganic encapsulation layer IEL2 may be formed on the organic encapsulation layer OEL. The second inorganic encapsulation layer IEL2 may extend from the third area A3 to the first area A1. In the second area A2, the second inorganic encapsulation layer IEL2 may be formed on the organic encapsulation layer OEL. In the second area A2 where the organic encapsulation layer OEL is not formed, the second inorganic encapsulation layer IEL2 may be formed on the first inorganic encapsulation layer IEL1.

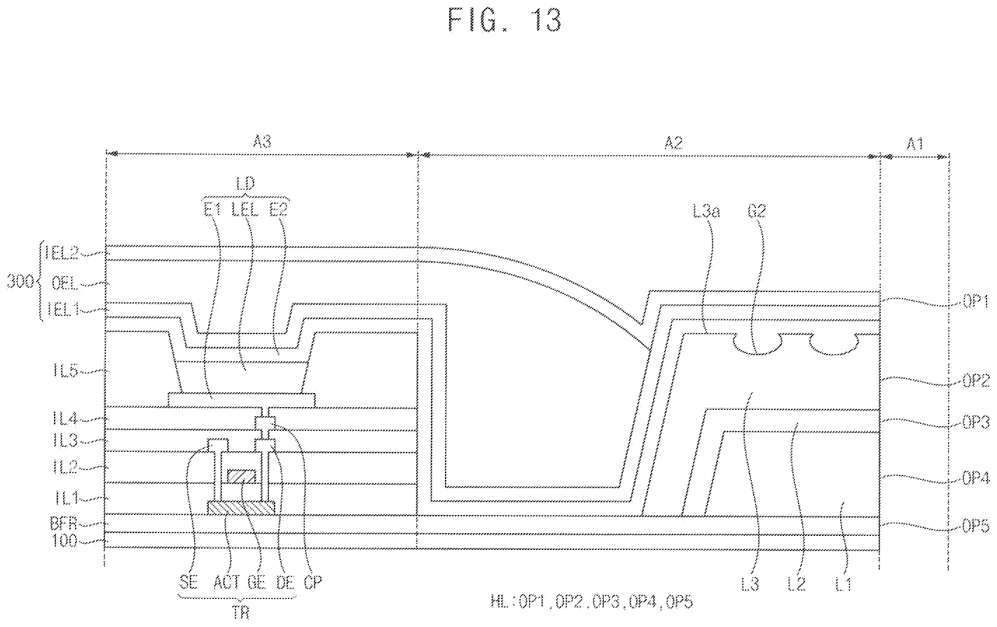

Referring to FIG. 13, a hole HL may be formed in the first area A1. The hole HL may penetrate the encapsulation layer 300. A first opening OP1 overlapping the first area A1 may be formed in the encapsulation layer 300. The hole HL may penetrate the third layer L3. A second opening OP2 overlapping the first area A1 may be formed in the third layer L3. The hole HL may penetrate the second layer L2. A third opening OP3 overlapping the first area A1 may be formed in the second layer L2. The hole HL may penetrate the first layer L1. A fourth opening OP4 overlapping the first area A1 may be formed in the first layer L1. The hole HL may penetrate the buffer layer BFR and the substrate 100. A fifth opening OP5 overlapping the first area A1 may be formed in the buffer layer BFR and the substrate 100.

The first to fifth openings OP1, OP2, OP3, OP4, and OP5 may be concurrently (e.g., simultaneously) formed. The first to fifth openings OP1, OP2, OP3, OP4, and OP5 may form the hole HL. The first to fifth openings OP1, OP2, OP3, OP4, and OP5 may overlap each other. Also, each of the first to fifth openings OP1, OP2, OP3, OP4, and OP5 may have substantially the same shape. Each of the first to fifth openings OP1, OP2 OP3, OP4, and OP5 may have substantially the same shape as that of the first area A1. For example, each of the first to fifth openings OP1, OP2, OP3, OP4, and OP5 may have a substantially circular shape. However, embodiments according to the present disclosure are not limited thereto.

As the hole HL is formed, the first groove G1 overlapping the first area A1 may be removed. The second groove G2 overlapping the second area A2 may not be removed. The second groove G2 may have the ring shape surrounding the hole HL.

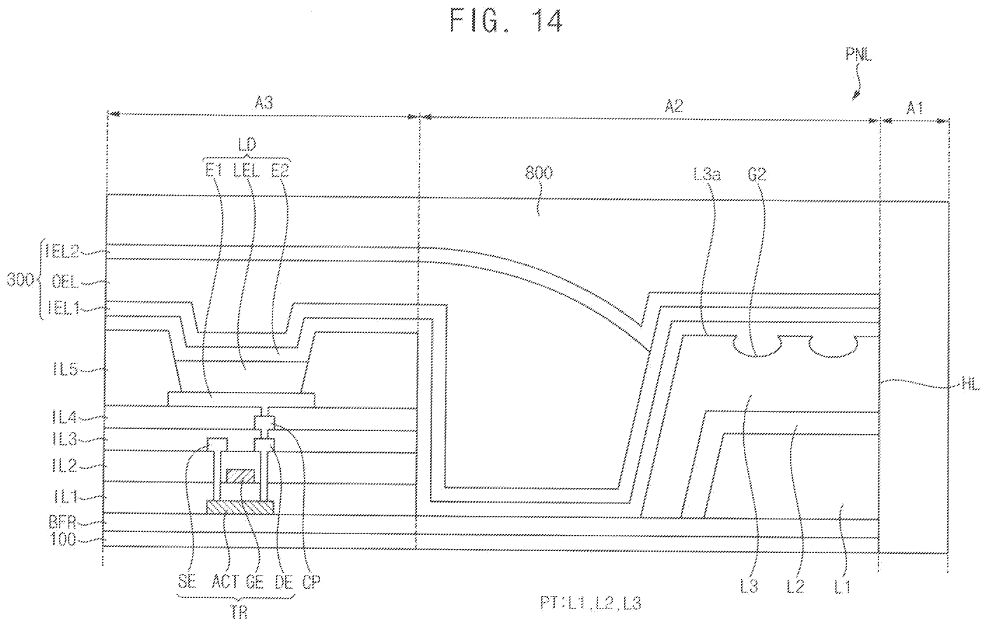

Referring to FIG. 14, in the first area A1, the second area A2, and the third area A3, a filling layer 800 may be formed. In the second area A2 and the third area A3, the filling layer 800 may be formed on the second inorganic encapsulation layer IEL2. The filling layer 800 may be formed in the hole HL overlapping the first area A1. A functional module may be formed under the filling layer 800 formed in the first area A1. However, embodiments according to the present disclosure are not limited thereto, and the filling layer 800 may be only in the first area A1 and the second area A2.

In an embodiment, the method of manufacturing the display panel may be performed without removing a portion of the partition PT before the groove G is formed. Also, in the method of manufacturing the display panel, the groove G may be formed on the upper surface L3a of the third layer L3. Accordingly, an additional process for flattening the step may be omitted. For example, the manufacturing process of the display panel PNL may be simplified. As the manufacturing process of the display panel PNL is simplified, a manufacturing time and cost for manufacturing the display panel PNL may be reduced.

The display panel and the method of manufacturing the display panel according to the embodiments may be applied to a display device included in a computer, a notebook, a mobile phone, a smartphone, a smart pad, a PMP, a PDA, an MP3 player, and/or the like.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

Although the display panel and the method of manufacturing the display panel according to the embodiments have been described with reference to the drawings, the illustrated embodiments are examples, and may be modified and changed by a person having ordinary skill in the art without departing from the spirit and scope of the present disclosure as defined by the following claims and equivalents thereof.

What is claimed is:

1. A display panel comprising:
a substrate comprising a first area, a second area surrounding the first area, and a third area surrounding the second area;
a partition on the substrate in the second area, comprising a first layer and a second layer on the first layer, and comprising at least one groove on an upper surface of the second layer; and
a display element layer on the substrate in the third area and adjacent to the partition.

2. The display panel of claim 1, wherein a depth of the groove is less than a length from an upper surface of the substrate to the upper surface of the second layer.

3. The display panel of claim 1, wherein a hole overlapping the first area is included in the partition and the substrate.

4. The display panel of claim 3, wherein the groove comprises a ring shape surrounding the hole in a plan view.

5. The display panel of claim 1, wherein the first layer and the second layer comprise a same material.

6. The display panel of claim 1, wherein the display element layer comprises:
a transistor;
a first electrode on the transistor and connected to the transistor;
a light emitting layer on the first electrode; and
a second electrode on the light emitting layer.

7. The display panel of claim 6, further comprising:
a planarization layer in the third area and between the transistor and the first electrode.

8. The display panel of claim 7, wherein the planarization layer comprises a same material as the first layer.

9. The display panel of claim 7, further comprising:
a pixel defining layer on the planarization layer, under the second electrode, and in the third area.

10. The display panel of claim 9, wherein the pixel defining layer comprises a same material as the second layer.

11. A method of manufacturing a display panel, the method comprising:
forming a first layer on a substrate and in a first area and a second area surrounding the first area;
forming a second layer on the first layer in the first area and the second area;
forming at least one groove on an upper surface of the second layer; and
forming a display element layer on the substrate and in a third area surrounding the second area.

12. The method of claim 11, further comprising:
forming a hole penetrating the first layer, the second layer, and the substrate; and
forming a filling layer overlapping the first area in the hole.

13. The method of claim 12, wherein the groove comprises a ring shape surrounding the hole in a plan view.

14. The method of claim 12, wherein forming the hole comprises:
forming a first opening overlapping the first area in the second layer;
forming a second opening overlapping the first area in the first layer; and
forming a third opening overlapping the first area in the substrate.

15. The method of claim 11, wherein the groove overlaps at least one of the first area and the second area.

16. The method of claim 11, wherein forming the display element layer comprises:
forming a transistor;
forming a first electrode connected to the transistor on the transistor;
forming a light emitting layer on the first electrode; and
forming a second electrode on the light emitting layer.

17. The method of claim 16, wherein forming the display element layer further comprises forming a planarization layer on the transistor.

18. The method of claim 17, wherein the planarization layer is formed concurrently with the first layer.

19. The method of claim 16, wherein forming the display element layer further comprises forming a pixel defining layer on the first electrode.

20. The method of claim 19, wherein the pixel defining layer is formed concurrently with the second layer.
